(19) United States
(12) Patent Application Publication
(10) Pub. No.: US 2014/0326277 A1
(43) Pub. Date: Nov. 6, 2014

(54) APPARATUS AND METHOD FOR PLASMA TREATMENT OF SURFACES

(71) Applicant: Maschinenfabrik Reinhausen GmbH, Regensburg (DE)

(72) Inventors: Stefan Nettesheim, Berlin (DE); Klaus Forster, Bad Abbach (DE); Dariusz Korzec, Wenzenbach (DE)

(21) Appl. No.: 14/333,217

(22) Filed: Jul. 16, 2014

Related U.S. Application Data
(63) Continuation of application No. PCT/EP2013/050293, filed on Jan. 9, 2013.

(30) Foreign Application Priority Data
Jan. 17, 2012 (DE) 102012000689.6
Aug. 8, 2012 (DE) 102012107282.5

(51) Int. Cl. H01J 37/32; B08B 7/00

(52) U.S. Cl. CPC H01J 37/32009; B08B 7/00; H01J 2237/335; H01J 2237/327; H01J 2237/20292
USPC 134/1.1; 156/345.33

(57) ABSTRACT

A method and a device for the plasma treatment of surfaces of at least one workpiece. At least one plasma source is connected to an energy source in order to generate a plasma. A closed area is in fluid connection to the at least one plasma source. At least one suction unit is used to adjust a pressure difference between the at least one plasma source and the closed area.

### CROSS-REFERENCE TO RELATED APPLICATIONS

This application is filed under 35 U.S.C. §120 and §365(c) as a continuation of International Patent Application PCT/EP2013/050293, filed Jan. 9, 2013, which application claims priority from German Patent Application No. 10 2012 000 689.6, filed Jan. 17, 2012 and German Patent Application No. 10 2012 107 282.5, filed Aug. 8, 2012, which applications are incorporated herein by reference in their entireties.

### FIELD OF THE INVENTION

The invention relates to a method and an apparatus for plasma treatment of surfaces. In particular, the invention is suitable for a gentle plasma treatment of thermally labile surfaces. The plasma treatment may, for example, be an activation, cleaning, degreasing, or deoxidation of surfaces. To this end at least one plasma source produces a plasma, and the plasma is fed into a closed space with which the at least one plasma source is in fluid communication. Workpieces with surfaces to be treated are placed in the closed space or the workpiece itself is part of the closed space. An extraction establishes a pressure difference between the closed space and the at least one plasma source.

### BACKGROUND OF THE INVENTION

Applying an arc expanding into a vacuum for large-area plasma treatment has been known for a long time. U.S. Pat. No. 3,010,009 (A. C. Ducati) describes a thermal treatment of workpieces.

U.S. Pat. No. 3,839,618 (Muehlberger) describes a method for coating surfaces of workpieces by means of a low-pressure plasma.

U.S. Pat. No. 6,872,428 (Yang et al.) addresses the problem of large-area or double-sided plasma treatment of workpieces and provides a solution to the problem by using a plurality of arc plasma jets.

U.S. Pat. No. 5,853,815 (Muehlberger) describes an apparatus for coating a large-area substrate using a low-pressure plasma, to which a powder is fed, expanding from an arc. By a tilting movement of a plasma generator large areas can be coated.

In the International Patent Application WO 2010/089175 (Gindrat et al.) an apparatus and method for plasma treatment are disclosed wherein a guide tube is provided to protect a plasma jet from contamination with a degenerate powder of a coating process.

To protect a plasma beam from air turbulence in the vicinity of a plasma torch, the International Patent Application WO 2011/094224 (Molz et al.) provides a shield made of perforated sheet.

The unpublished International Patent Application PCT/EP2012/060497 discloses an apparatus and a method for plasma treatment of hollow bodies. A hollow body is placed into a pressure chamber in which a pressure difference with respect to a plasma source can be produced by means of an extraction device. The plasma source is located outside the pressure chamber. By a control unit, a power supply is controlled such that a pulsating plasma is generated. A plasma guide with a respective outlet for an influx of plasma extends into a hollow body to be treated.

The unpublished International Patent Application PCT/EP2012/060494 discloses an apparatus and a method for the plasma treatment of surfaces. A workpiece is placed in a pressure chamber, in which, by a pump, a lower pressure relative to a plasma source can be generated. The plasma source is located outside the pressure chamber. By a plasma supply control unit an inflow of a plasma beam into the pressure chamber and onto the workpiece can be set. Furthermore, a modulated plasma can be generated.

German publication DE 102 03 543 discloses an apparatus for generating an atmospheric glow discharge plasma by which a particularly homogeneous processing of a substrate is to be achieved when used in apparatuses for the plasma treatment, in that a flow path of a gas supplied to a plasma source by a plurality of gas supply lines is maintained substantially the same.

German reference DE 195 32 412 discloses an apparatus and a method for surface treatment of workpiece surfaces. A treatment of workpieces having a relatively complicated relief is to be made possible by generating a collimated beam of a reactive medium by plasma discharge while supplying a working gas, and by exposing a surface to be treated to the generated beam. A uniform treatment of extended workpieces is to be achieved by a plurality of beam generators integrated in a common working head, the beam generators arranged in a row or interstitially in a plurality of rows.

The International Patent Application WO 2005/099320 (Foernsel) discloses an apparatus and a method for generating a low-pressure plasma jet from a plasma jet of higher pressure. This is produced in a plasma source which is supplied with a process gas and power from a high frequency high voltage field. The plasma source is connected to a low-pressure chamber, into which the workpiece is placed, and protrudes at least partly into it. In the low-pressure chamber a lower pressure relative to the plasma source is generated by a pump. An increase in the homogeneity of the plasma deposit on the surface of the workpiece according to one embodiment is achieved by two plasma sources, which are arranged in opposite side walls of the low-pressure chamber and directed towards each other.

By none of the prior art apparatuses and methods is it possible to subject workpieces of arbitrary shape made of arbitrary materials to a plasma treatment, either because too high a thermal or mechanical stress acts on the workpieces, or because the surfaces due to their size or contour are not entirely accessible for a plasma treatment, in particular not in a single operation. The prior art approaches to solving these problems are at the expense of simplicity and cost-effectiveness of the apparatuses and methods described.

### BRIEF SUMMARY OF THE INVENTION

The object of the invention is to provide an apparatus which is simple in construction and by which a gentle, uniform, and simultaneous plasma treatment of plural surfaces of arbitrarily shaped workpieces is possible.

This object is solved by an apparatus for the plasma treatment of surfaces of at least one workpiece comprising: a closed space, at least one plasma source connected with a power supply for the generation of a plasma, a single opening of the closed space provides fluid communication with a respective plasma distribution element which is located within the closed space, at least one extraction for setting a pressure difference between the at least one plasma source and the closed space and a plurality of plasma discharge openings each plasma distribution element exhibits.

It is a further object of the invention to develop a method by which a gentle, uniform, and simultaneous plasma treatment of plural surfaces of arbitrarily shaped workpieces is possible.

This object is achieved by a method for the plasma treatment of surfaces of at least one workpiece comprising the following steps: maintaining a pressure difference between at least one plasma source and a closed space by means of an extractions, generating a plasma in the at least one plasma source, supplying the plasma via a respective single opening of the at least one plasma source into a respective plasma distribution element located in the closed space and supplying in a directed fashion a plurality of plasma jets via a plurality of plasma discharge openings of each plasma distribution element to at least one surface of the at least one workpiece.

The inventive apparatus for plasma treatment of surfaces of at least one workpiece comprises at least one plasma source with a power supply for generating a plasma, a closed space which is in fluid communication with the at least one plasma source, and at least one extraction for setting a pressure difference between the at least one plasma source and the closed space.

Preferably, the plasma source operates under atmospheric pressure or elevated pressure, at least partial vacuum conditions prevail in the closed space, and the generated plasma is a plasma at atmospheric pressure, such as a blown arc. However, the plasma source is not limited to the generation of such a plasma, and the pressure conditions in the plasma source and the closed space can be freely adjusted. The setting of the pressure difference between the closed space and the at least one plasma source can be influenced or controlled not only by the extraction, but also by an opening, by which the closed space is in fluid communication with a respective plasma source. The at least one opening may be provided as a nozzle or valve in order to influence the shaping of the respective plasma jet in addition to the pressure conditions in the plasma source and the closed space. A further parameter for adjusting the pressure differences between the closed space and the at least one plasma source is the configuration of a gas supply, through which gas is supplied to the plasma source for the generation of the plasma. If, for example, the gas is introduced through the gas supply at a higher pressure with respect to the closed space, an excess-pressure plasma results. This excess pressure may be increased by generating a vacuum in the closed space. The at least one plasma source can be oriented with respect to the closed space as desired, even though plasma sources arranged vertically are shown in the embodiments of the inventive apparatus.

According to the invention at least one plasma distribution element, having a plurality of plasma discharge openings, is arranged downstream from each of the plasma sources.

By the at least one plasma distribution element the generated plasma can be divided so that a plurality of plasma jets can be generated from a plasma source. Therefore, neither power nor gas supply is necessary in the immediate vicinity of a plasma jet for generating the plasma jet, and a plurality of plasma jets may be directed simultaneously onto at least one surface of a workpiece, independently of the position of the at least one plasma source. Furthermore, as the plasma from a plasma source is divided into plural plasma jets, larger surfaces can be treated, relative to the performance of the plasma source, power supply, gas supply and extraction. The at least one plasma distribution element may be composed of a plurality of hollow bodies, for example from cylindrical tube sections, analogous to tubing which can be used for the construction of gas or water pipe systems. In principle, all materials can be used which are suitable with regard to the mechanical and thermal stability, and which have a positive effect on the properties of the plasma, or at least not a negative effect.

The at least one plasma distribution element is configured such that a normal vector of a plane of each plasma discharge opening is directed onto a surface to be treated of the at least one workpiece. The normal vector of the plane of the respective plasma discharge opening defines a direction of a plasma jet.

The at least one plasma distribution element can be adjusted to the shape of the workpiece to be treated and/or to the desired type and intensity, respectively, of treatment of workpieces. The direction of the plasma jets is not based exclusively on the principle of a plasma expansion due to a pressure difference between the plasma jet and a space in which the workpiece is located. The plasma jets are supplied to at least one surface of a workpiece in a directed manner. The plurality of plasma jets generated by a plasma source can be controlled with respect to intensity, shape, volume, direction, opening angle, distance to the surface of the workpiece. Within the at least one plasma distribution element, the plasma jets may be identical or may differ with respect to the parameters mentioned in the previous sentence. Thus, both a homogeneous treatment of a plurality of surfaces and an intentionally differing treatment of different surfaces of a workpiece, or of different regions of a surface of a workpiece are possible. Possible parameters for the targeted control of intensity, shape, direction, opening angle, volume, distance to the surface of the workpiece of the plasma jets include the length of the flow path which the plasma has to flow before reaching the respective plasma discharge opening, the cross-section (shape of cross-section, area of cross-section) and/or cross-sectional profile (change in cross-sectional shape or cross-sectional area along the flow path) of each plasma guide in the plasma distribution element and/or the configuration of the plasma discharge openings. In the plasma discharge openings, for example, nozzles can be provided, by which the plasma jet is shaped, for example, widened. Furthermore, it is conceivable to provide valves in the plasma discharge openings to control the volume flow or the pressure of individual plasma jets independently over time. By a design of the surface properties (surface roughness, surface treatments, such as coatings) of the flow surfaces of the plasma distribution element, the plasma can also be affected. Essentially, the at least one plasma distribution element is a fluidic distribution system. Accordingly, for the configuration of the at least one plasma distribution element and for affecting the plasma jets, all parameters and laws of fluid dynamics can be taken into account, which can be taken into account for the design of general fluidic systems, such as gas or water pipe systems.

In an advantageous embodiment of the inventive apparatus, the plasma discharge openings of the at least one plasma distribution element for the plasma treatment of an essentially cuboid workpiece are arranged non-uniformly along an outer contour of the workpiece.

In one embodiment of the inventive apparatus, the at least one plasma distribution element is configured as a fractal plasma distribution element.

In general, a geometry is called fractal, where a magnification of a section of the geometry in principle corresponds with its overall structure. An example of this is the multi-branched structure of biological fluid channels. By a fractal plasma distribution element of the present invention a plasma distribution element is meant which is configured such that the plasma is divided along the direction of flow to the plasma discharge openings such that a plurality of identical plasma jets is produced. The identical partial flows, or the identical plasma jets, respectively, preferably are achieved in such a way that the path of the plasma from the plasma source to the plasma discharge openings is of equal length. As a result, plural plasma jets, identical with respect to all parameters can be generated from a plasma source, and can be supplied to at least one surface of at least one workpiece. Thus, a particularly homogeneous treatment of a surface of a workpiece is possible. However, the same flow paths between the plasma source and plasma discharge openings do not guarantee a homogeneous plasma distribution under certain circumstances. Some further factors such as the cross-sectional areas or the changes in the cross-sectional areas along the flow path or the turbulence of the plasma in the plasma duct separation also play an important role for uniform plasma distribution. At this point, again, reference is made to all known parameters and laws of fluid dynamics. Such factors may be considered in the design of the at least one plasma distribution element, so that by the fractal plasma distribution element a uniform and homogeneous plasma distribution is ensured while minimizing the necessary pressure difference between the plasma source and the closed space. With the fractal plasma distribution element, rectangular or hexagonal plasma jet matrices, among others, are realizable.

For plasma treatment of a planar extended workpiece, the apparatus of the invention can provide a plasma distribution element configured such that plasma discharge openings are arranged opposite a top side and a bottom side of the planar extended workpiece.

By a planar extended workpiece a body is meant which has a greater, in amount, width than height. Application related examples of planar extended workpieces are printed circuit boards, in particular double-sided electronic circuit boards, films, boards, textile webs or metal sheets. The longitudinal extent of the workpieces is not limited. Endless workpieces, such as film webs, can be treated with the inventive apparatus, too. To this end, for example, a pressure lock system can be provided, wherein the closed space is connected to an upstream pressure lock and to a downstream pressure lock in order to introduce the workpieces into the closed space and to remove them, by means of a moving means. Therein it is important to design the lock system such that the pressure difference between the plasma source and the closed space can be maintained.

Furthermore, the closed space may be provided at opposite boundaries with a respective at least one plasma source, to which is assigned a respective plasma distribution element, so that the plasma discharge openings of each plasma distribution element are arranged opposite the top side and bottom side of the planar extended workpiece.

Both identical and different plasma sources and/or plasma distribution elements may be arranged. A plasma source can be supplied from a gas supply specifically assigned to it and from a power supply specifically assigned to it. It is also possible to supply the plasma sources by a common gas supply and/or power supply. Between the respective plasma sources and the closed space equal as well as different pressure differences may be set. Thus, in the treatment of a planar extended body, for example, a first plasma, supplied to the top side of the planar extended body, may have a higher pressure than a second plasma, supplied to the bottom side. The openings of the closed space through which the closed space is in fluid communication with the plasma sources, depending on the respective plasma source, can be configured identically or differently. Analogously to all other embodiments, the openings, for example, may be nozzles or valves. The distance between the plasma discharge openings of the at least one plasma distribution element opposite the top side of the workpiece and the top side of the workpiece, can be equal, larger or smaller than the distance between the plasma discharge openings of the at least one plasma distribution element opposite the bottom side of the workpiece and the bottom side of the workpiece. By means of a moving means the distances from the plasma discharge openings to the at least one surface of the workpiece can also be changeable over time. It is possible to subject the top side and the bottom side of the planar extended workpiece to an identical plasma treatment or to apply different plasma jets to the top side and the bottom side of the planar extended workpiece. Here, too, a homogeneous treatment of plural surfaces or an intentionally different treatment of different surfaces of a workpiece or of different areas of a surface of a workpiece are possible. In the described embodiments for the treatment of planar extended workpieces, the plasma distribution elements can be configured as fractal plasma distribution elements, too.

In a further advantageous embodiment of the apparatus according to the invention, the plasma discharge openings of the at least one plasma distribution element can be distributed homogeneously around a periphery of the surface of the workpiece to be treated.

Such a configuration is particularly suitable for the treatment of round bodies. These may exhibit an arbitrarily shaped circumference. Besides circular, oval or elliptical bodies, also bodies having a complex shape, which is not axially symmetric, can be treated. The plasma discharge openings can be distributed according to the surface to be treated in such a manner that the plasma jets cover the circumference of the workpiece uniformly and a homogeneous treatment of fibers, fiber bundles, cables, tubes, rods, wires and similar workpieces therefore is possible. It should be reiterated at this point, however, that an intentionally different treatment of different surfaces of a workpiece or of different regions of a surface of a workpiece is possible with the apparatus according to the invention. In this embodiment using a lock system as described above is particularly advantageous, so that a continuous treatment of workpieces, without limitation of their longitudinal extension may be achieved.

In one embodiment of the apparatus according to the invention the at least one plasma distribution element is a hollow body and the plasma discharge openings are distributed uniformly over a lateral surface of the at least one plasma distribution element.

According to this embodiment, a treatment of at least one inner surface of at least one workpiece is possible. The at least one plasma distribution element is positioned within the workpiece and the plasma discharge openings of the at least one plasma distribution element are arranged in relation to the inner surface of the workpiece.

The apparatus according to the invention is suitable for any plasma treatment of surfaces. Examples are the activation, cleaning, for example, a cleaning of the inside of pipes prior to a protective coating, degreasing, deoxidation, for example, a reduction of oxides on metal contacts of a double-sided printed circuit board, for example, with a hydrogen-containing plasma from a forming gas or hydrogen-argon gas mixture, or an oxidation, for example, with an oxygen-containing plasma, starting from an air-/argon-oxygen mixture.

In a particularly advantageous embodiment of the apparatus according to the invention, the closed space is defined by the workpiece itself, which is formed as a hollow body, a supply flange and an extraction flange. Therein it may be provided that into the closed space there extends, through the supply flange, at least one supply line, on the free end of which the at least one plasma source and the at least one plasma distribution element are located, wherein the closed space, via an extraction flange, is in fluid communication with the extraction. Therein the plasma discharge openings of the plasma distribution element may be homogeneously distributed with respect to an inner surface of workpiece shaped as a hollow body.

By this arrangement the process chamber is omitted, whereby a particularly simple, compact and cost-effective construction of the apparatus according to the invention can be provided. Regarding this embodiment analogously to the previously described embodiments, in this case, the inner surfaces of the closed space are treated. The supply flange and the extraction flange are applied to the workpiece to be treated, in order to maintain the pressure difference between the plasma source and the closed space. Sealing elements may be provided as separate components or be integrated into the supply flange and the extraction flange.

In all embodiments of the apparatus according to the invention, the power supply may be a pulsed direct-current source, so that a pulsating plasma can be generated.

The plasma source, according to the invention, is supplied with energy from a power supply. By pulsing the energy supplied or the power supplied, a pulsating plasma can be generated. In particular, the current pulses can be DC pulses with fixed or variable values for the pulse duration, pulse interval, and/or magnitude of the current. By a pulsating plasma a mean enthalpy of the plasma jets can be lowered, and so a thermal power, a thermal and/or electrostatic strain from the plasma to the workpiece may be set, in particular reduced. Relative to the use of a continuous or static plasma the advantage results that the average pressure in the closed space can be significantly lower. Therefore, a treatment of both thermally and mechanically unstable workpieces, such as plastic films, biomaterials, fiber fabrics, pulp, thin metal foils or plastic bottles is feasible. It should be noted that the pulsed direct-current source in the description of the present invention is to be understood both as a current source, i.e. as a power supply in which a current is used as the reference variable, and as a voltage source, i.e. as a power supply in which a voltage is used as the reference variable. The power supply therefore may also be a pulsed DC voltage source. Although reference is made in the description of the invention and in the accompanying figures primarily to electrical power supplies, it should be noted that the power for generating the plasma may also be provided in other forms. Thus, the power supply can for example also be a radiation source (e.g. a microwave source) or a heat source. Also with the use of such power supplies generating a pulsating plasma is conceivable.

Furthermore, in all embodiments of the apparatus according to the invention a moving means may be provided which produces a relative movement between the plasma discharge openings and the at least one workpiece.

Thus, uniform or non-uniform linear, rotary or oscillating movements, among others, can be performed between the workpiece and the plasma jets. The movement types described can be carried out separately, but also superposed. It is conceivable to provide various movement patterns over the course of time, in order to subject specific areas of a surface to a desired plasma treatment. A relative movement between the workpiece and the plasma jets can have a supportive effect on the homogeneity of the treatment, and can increase further the maximum surface area that can be treated with the generated plasma of a plasma source. It is possible to perform the relative motion on the plasma and/or on the workpiece side. With respect to the practical realization of the moving means, inter alia all the devices are conceivable which, for example, are used in machine tools for the controlled movement of tool or workpiece.

The inventive method for plasma treatment of surfaces of at least one workpiece is characterized in that, by means of an extraction, a pressure difference between at least one plasma source and a closed space is maintained. In the at least one plasma source, a plasma is generated, which is supplied into the closed space and is divided into a plurality of plasma jets by means of a plasma distribution element that is arranged downstream of a respective plasma source. The plasma jets are applied to at least one surface of the at least one workpiece in a directed fashion through a plurality of plasma discharge openings of the at least one plasma distribution element.

In an exemplary sequence of the inventive method, the workpiece whose surfaces are to be treated is introduced into the closed space, or itself forms the closed space partially or completely. By the extraction, by an opening formed in the closed space as a nozzle, and by a control of a gas supply to the plasma source, a pressure difference between at least one plasma source and a closed space is created and/or maintained. In the closed space, for example, a rough vacuum is generated. In the at least one plasma source a plasma is generated, which is fed into the closed space and divided into plural plasma jets by means of a plasma distribution element arranged downstream from a respective plasma source, wherein the plasma jets may be equal or may differ with respect to intensity, shape, direction, opening angle, volume, distance to surface of workpiece. The plasma jets are supplied through a plurality of plasma discharge openings of the at least one plasma distribution element to at least one surface of the at least one workpiece in a directed fashion. By a pulsed direct-current source a pulsating plasma is generated in the plasma source. Between the plasma discharge openings of the at least one plasma distribution element, and hence the plasma jets, and the at least one workpiece, a relative movement is carried out, which can be varied over the course of time of the plasma treatment with respect to the movement pattern and/or speed of movement. All forms of movement may also be superposed.

### BRIEF DESCRIPTION OF THE DRAWINGS

The nature and mode of operation of the present invention will now be more fully described in the following detailed description of the invention taken with the accompanying drawing figures, in which:

FIG. 1 is a schematic sectional view of an embodiment of the inventive apparatus for plasma treatment of surfaces;

FIG. 2 is a schematic sectional view of an embodiment of the apparatus for plasma treatment of surfaces with a fractal plasma distribution element;

FIG. 3 is a schematic sectional view of an embodiment of the apparatus for plasma treatment of surfaces, wherein plasma distribution elements are arranged opposite a top side and a bottom side of a planar extended workpiece, respectively;

FIG. 4 is a schematic sectional view of an embodiment of the apparatus for plasma treatment of surfaces, wherein plasma discharge openings of a plasma distribution element are distributed around a periphery of a workpiece; and

FIG. 5 is a schematic sectional view of an embodiment of the apparatus for plasma treatment of surfaces, wherein a closed space is defined by the workpiece itself, one supply flange and one extraction flange.

These examples of more specific embodiments are not to be regarded as limitations upon the scope of the invention.

### DETAILED DESCRIPTION OF THE INVENTION

At the outset, it should be appreciated that like drawing numbers on different drawing views identify identical, or functionally similar, structural elements of the invention. While the present invention is described with respect to what is presently considered to be the preferred aspects, it is to be understood that the invention as claimed is not limited to the disclosed aspects.

Furthermore, it is understood that this invention is not limited to the particular methodology, materials and modifications described and, as such, may, of course, vary. It is also understood that the terminology used herein is for the purpose of describing particular aspects only, and is not intended to limit the scope of the present invention, which is limited only by the appended claims.

Unless defined otherwise, all technical and scientific terms used herein have the same meaning as commonly understood to one of ordinary skill in the art to which this invention belongs. Although any methods, devices or materials similar or equivalent to those described herein can be used in the practice or testing of the invention, the preferred methods, devices, and materials are now described.

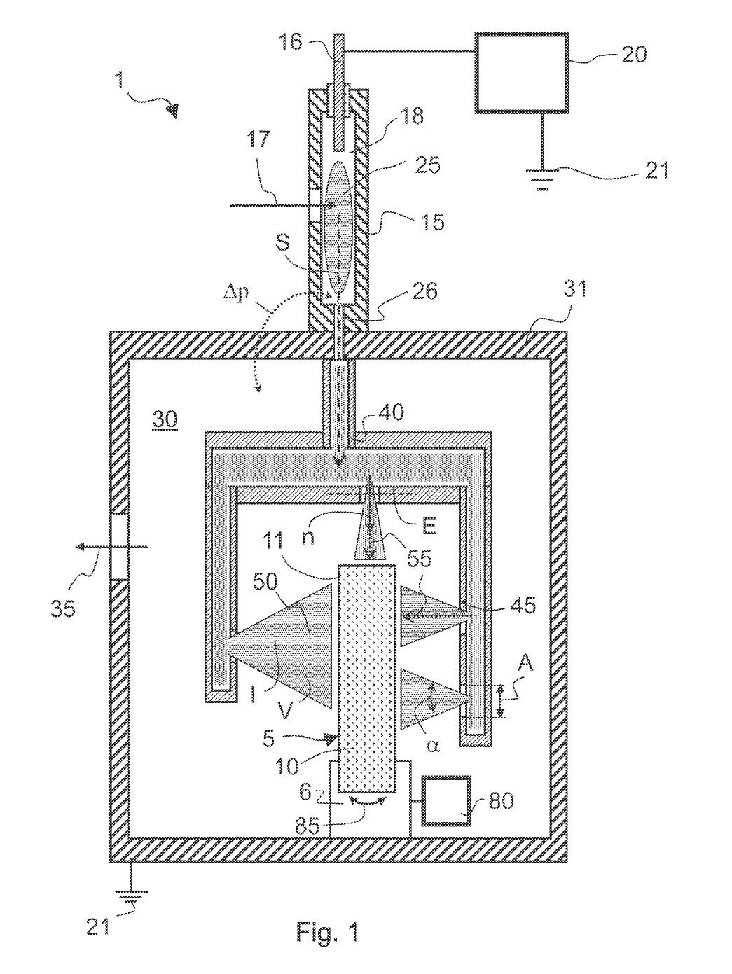

FIG. 1 shows inventive apparatus 1 for plasma treatment of surfaces 5. In closed space 30, workpiece 10 to be treated is positioned using workpiece holder 6. Closed space 30 essentially is defined by process chamber 31. By extraction 35, pressure difference Δp can be set in closed space 30 with respect to discharge space 18 of plasma source 15. Plasma source 15 is located outside of closed space 30, but may also be arranged within closed space 30. Via gas supply 17 plasma gas is supplied into discharge space 18 of plasma source 15. A voltage is applied to electrode 16 by power supply 20 connected to ground potential 21. Power supply 20 is a pulsed DC source in the embodiment shown. To avoid electrostatic charges and parasitic current flow, plasma source 15, process chamber 31 and power supply 20 are connected to ground potential 21. Closed space 30 is in fluid communication with plasma source 15 through opening 26. Opening 26 may, for example, be a nozzle or valve, in order to control the flow of plasma 25 in flow direction S, and pressure difference Δp. Downstream in flow direction S from plasma source 15 plasma distribution element 40 is located, having plurality of plasma discharge openings 45. Plasma distribution element 40 is configured such that normal vector n of plane E of each plasma discharge opening 45 is directed to surface 5 to be treated of workpiece 10. Normal vector n of plane E of respective plasma discharge opening 45 defines direction 55 of each plasma jet 50. It can be seen that plasma discharge openings 45 and thence direction 55 of plasma jets 50 are non-uniformly distributed around outer contour 11 of workpiece 10. Plasma distribution element 40, in the embodiment shown here, exhibits plasma discharge openings 45 of different cross-section A, such that plasma jets 50 with different opening angles a result. Intensity I and volume V of each of plasma jets 50 may in some cases be controlled by cross-section A of plasma discharge openings 45, too. By moving means 80, workpiece holder 6 which holds workpiece 10, is moved, whereby relative movement 85 between workpiece 10 and plasma jets 50 is achieved.

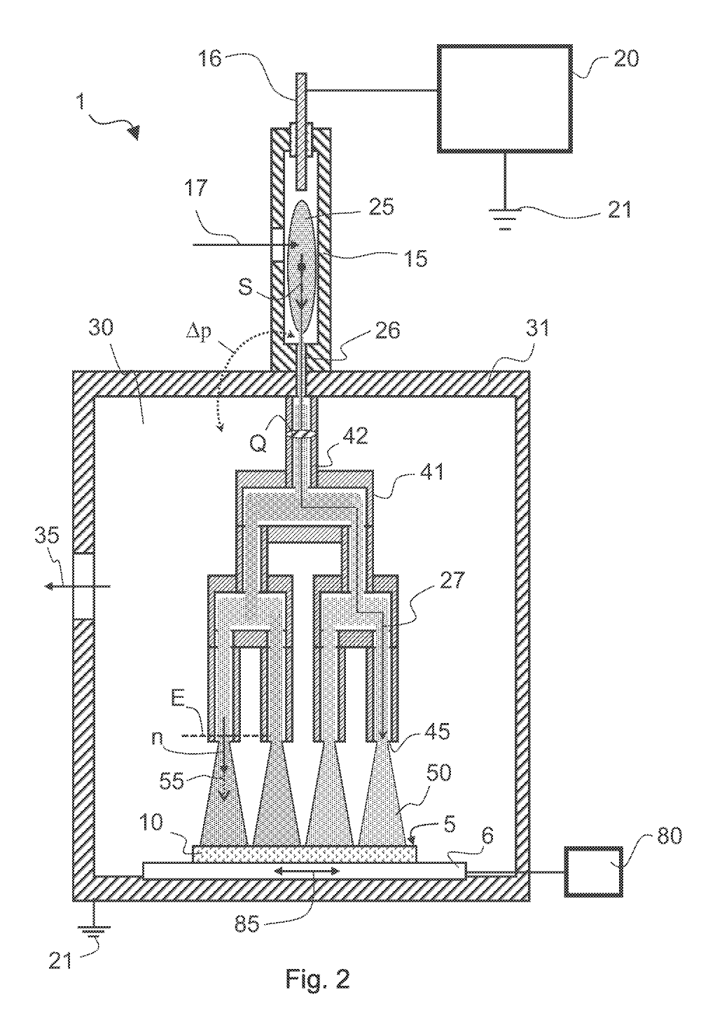

FIG. 2 shows inventive apparatus 1 for plasma treatment of surfaces 5 with fractal plasma distribution element 41, which is composed of plural pipe sections 42 of the same cross-section Q. In closed space 30, workpiece 10 to be treated is positioned using workpiece holder 6. Closed space 30 essentially is limited by process chamber 31. By extraction 35, pressure difference Δp can be set in closed space 30 with respect to discharge space 18 of plasma source 15. Plasma source 15 is located outside of closed space 30, but may also be arranged within closed space 30. Via gas supply 17 plasma gas is supplied into discharge space 18 of plasma source 15. A voltage can be applied to electrode 16 by power supply 20 connected to ground potential 21. The power supply is pulsed DC source 20 in the embodiment shown. To avoid electrostatic charges and parasitic current flow, plasma source 15, process chamber 31 and power supply 20 are connected to ground potential 21. Closed space 30 is in fluid communication with plasma source 15 through opening 26. Opening 26 is designed as a nozzle in order to control the flow of plasma 25 in flow direction S, and pressure difference Δp. Downstream in flow direction S from plasma source 15 fractal plasma distribution element 41 having plurality of plasma discharge openings 45 is located. Fractal plasma distribution element 41 is configured such that normal vector n of plane E of each plasma discharge opening 45 is directed to surface 5 to be treated of workpiece 10. Normal vector n of plane E of respective plasma discharge opening 45 defines direction 55 of each plasma jet 50. Fractal plasma distribution member 41 is configured such that average path 27 of plasma 25 from plasma source 15 to respective plasma discharge opening 45 of fractal plasma distribution member 41, in which plasma 25 is divided into identical plasma jets 50, is of equal length. By moving means 80, workpiece holder 6 which holds workpiece 10 is moved, whereby relative movement 85 between workpiece 10 and plasma jets 50 is achieved.

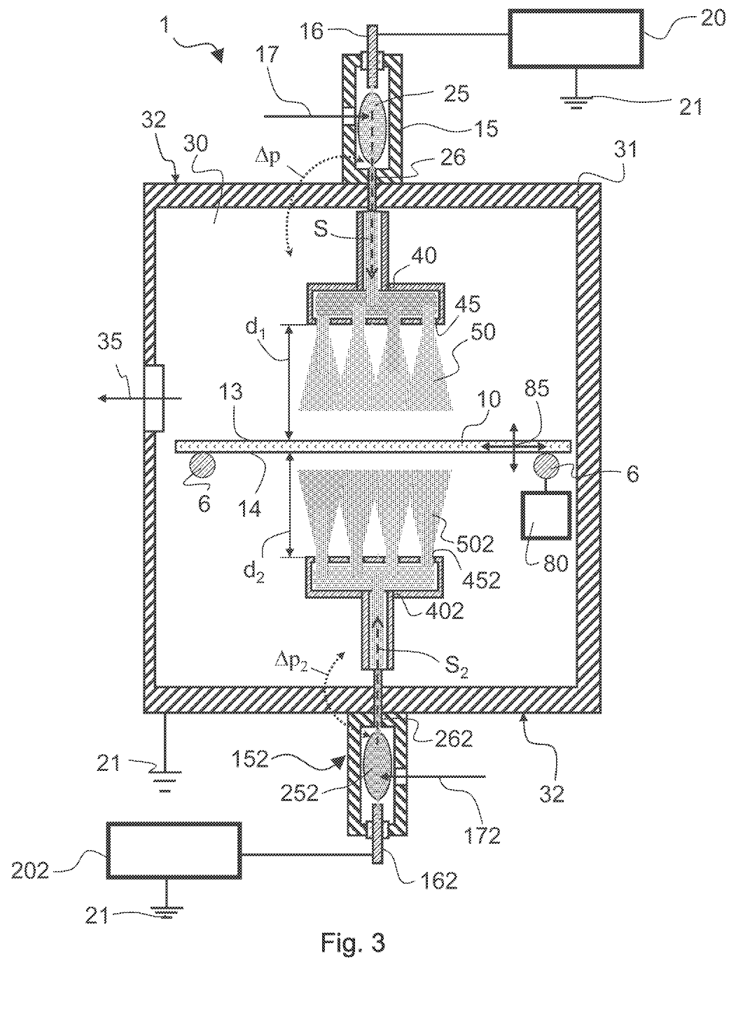

FIG. 3 shows inventive apparatus 1 for plasma treatment of surfaces 5, wherein planar extended workpiece 10 is located between plasma distribution element 40 and further plasma distribution element 402 in closed space 30. Plasma distribution element 40 is located opposite top side 13 of workpiece 10, and further plasma distribution element 402 is located opposite bottom side 14 of planar extended workpiece 10. Plasma distribution element 40 divides plasma 25 generated in plasma source 15 into plurality of plasma jets 50, which exit from plasma discharge openings 45 and are supplied in a directed manner to top side 13 of workpiece 10. Further plasma distribution element 402 divides plasma 252 generated in plasma source 152 into plurality of plasma jets 502, which exit from plasma discharge openings 452 and are supplied in a directed fashion to bottom side 14 of workpiece 10. Plasma source 15 is connected to power supply 20, which is connected to ground potential 21, and to gas supply 17. Power supply 20 is also connected to electrode 16. Plasma source 152 is connected to power source 202, which is also connected to ground potential 21, and to gas supply 172. Power supply 202 is also connected to electrode 162. Closed space 30 essentially is limited by process chamber 31. By extraction 35 and gas supplies 17, 172 pressure differences Δp and Δp₂ can be set in closed space 30 with respect to plasma sources 15, 152. Plasma sources 15, 152 are located outside of closed space 30, but may also be arranged within closed space 30. The power supplies are pulsed DC sources 20, 202 in the embodiment shown. To avoid electrostatic charges and parasitic current flow, plasma sources 15, 152, process chamber 31, and power supplies 20, 202 are connected to ground potential 21. Closed space 30 is in fluid communication with plasma sources 15, 152 through openings 26, 262. Openings 26, 262 are nozzles, in order to control the flow of plasmas 25, 252 in flow directions S and S₂, respectively, and pressure differences Δp and Δp₂, respectively. Plasma discharge openings 45 of at least one plasma distribution element 40 opposite top side 13 of workpiece 10 are at distance d₁ to top side 13 of workpiece 10. Plasma discharge openings 452 of at least one further plasma distribution element 402 opposite bottom side 14 of workpiece 10 are at distance d₂ to bottom side 14 of workpiece 10. By means of moving means 80, a workpiece holder, which is designed as roller device 6, is moved, whereby relative movement 85 between workpiece 10 and plasma jets 50, 502 is achieved.

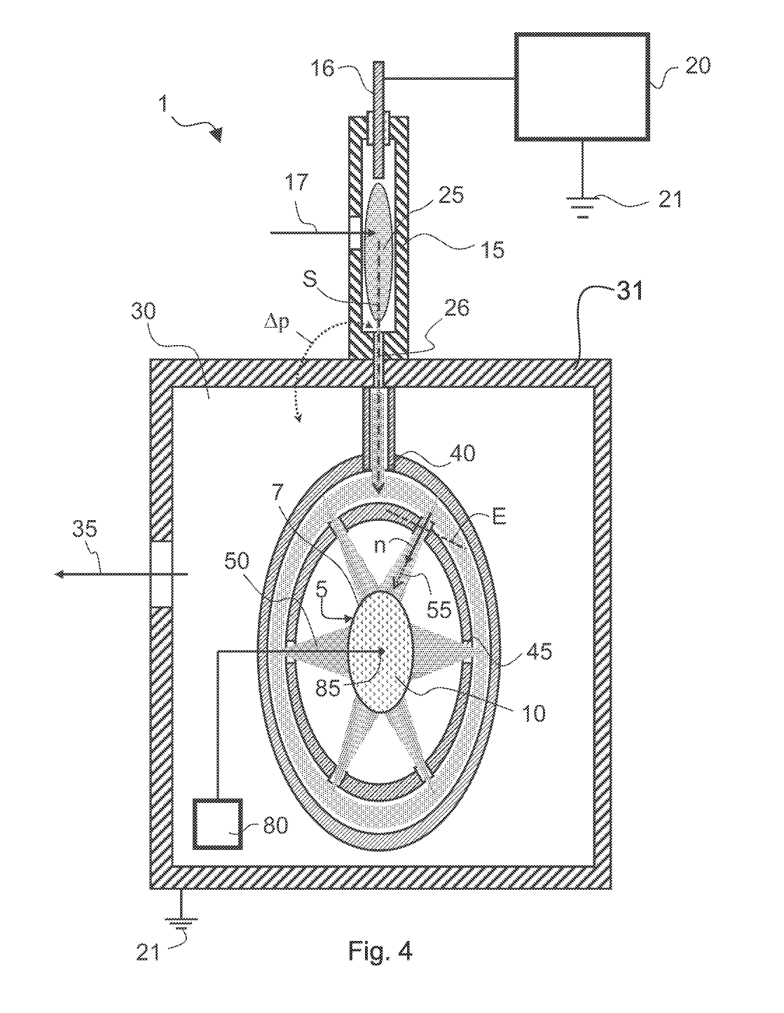

FIG. 4 shows inventive apparatus 1 for plasma treatment of surfaces 5. In closed space 30 workpiece 10 to be treated, formed as an oval round body, is positioned using a workpiece holder (not visible in FIG. 4). Closed space 30 essentially is limited by process chamber 31. By extraction 35, pressure difference Δp can be set in closed space 30 with respect to plasma source 15. Plasma source 15 here is located outside of closed space 30. Via gas supply 17 plasma gas is supplied into plasma source 15. A voltage can be applied to electrode 16 by power supply 20 connected to ground potential 21. The power supply is pulsed DC source 20 in the embodiment shown. To avoid electrostatic charges and parasitic current flow, plasma source 15, process chamber 31 and power supply 20 are connected to ground potential 21. Closed space 30 is in fluid communication with plasma source 15 through opening 26. Opening 26 may, for example, be a nozzle or valve, in order to control the flow of plasma 25 in flow direction S, and pressure difference Δp. Downstream in flow direction S from plasma source 15 plasma distribution element 40 having plurality of plasma discharge openings 45 is located. Plasma distribution element 40 is configured such that normal vector n of plane E of each plasma discharge opening 45 is directed to surface 5 to be treated of workpiece 10. Normal vector n of plane E of respective plasma discharge opening 45 defines direction 55 of each plasma jet 50. Plasma discharge openings 45 of plasma distribution member 40 are homogeneously distributed around circumference 7 of surface 5 to be treated of workpiece 10. Plasma discharge openings 45, in accordance with surface 5 to be treated, are distributed such that plasma jets 50 cover circumference 7 of workpiece 10 uniformly. Thus, there is a particularly homogeneous treatment of surface 5 of workpiece 10. By moving means 80 relative movement 85 is performed between workpiece 10 and plasma jets 50. The relative movement is carried out perpendicular to the surface of the figure.

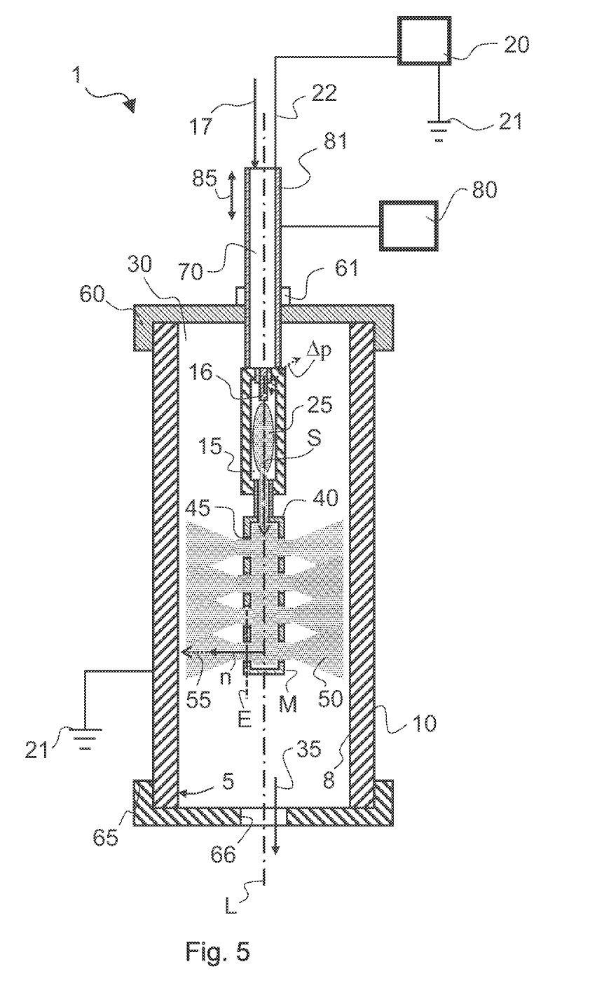

FIG. 5 shows a schematic sectional view of a further embodiment of the apparatus for plasma treatment of surfaces. In this particularly advantageous embodiment of inventive apparatus 1 closed space 30 is defined by the workpiece itself, formed as pipe 10, supply flange 60 and extraction flange 65. By extraction 35, pressure difference Δp can be set in closed space 30 with respect to plasma source 15. A voltage can be applied to electrode 16 by power supply 20 connected to ground potential 21. The power supply is pulsed DC source 20 in the embodiment shown. Plasma source 15, workpiece 10, and power supply 20 are connected to ground potential 21. Through supply flange 60 there extends supply line 70 which includes gas supply 17 and power supply 22. Supply line 70 extends into closed space 30. At the free end of supply line 70 plasma source 15 and plasma distribution element 40 are located. As with all embodiments of inventive apparatus 1, plasma distribution element 40 is configured such that normal vector n of plane E of each plasma discharge opening 45 is directed to surface 5 to be treated of workpiece 10. Normal vector n of plane E of the respective plasma discharge opening 45 defines direction 55 of each plasma jet 50. Plasma distribution element 40 is formed as a hollow body and plasma discharge openings 45 are distributed homogeneously over lateral surface M of plasma distribution element 40, in relation to inner surface 8 of workpiece 10, so that plasma jets 50 are distributed homogeneously over inner surface 8 of workpiece 10. Thus, a particularly homogeneous treatment of inner surface 8 of workpiece 10 results. Closed chamber 30 is in fluid communication with extraction 35 via extraction flange 65. In this embodiment, sealing element 66 is integrated into extraction flange 65 in order to maintain pressure difference Δp. The role of the seal to the supply side here is fulfilled by bushing 61. Alternatively, sealing element 66 could be incorporated into supply flange 60, too, and bushing 61 also be provided on the extraction side. By moving means 80, relative movement 85 is performed between workpiece 10 and plasma jets 50. Relative movement 85 is parallel to longitudinal axis L of workpiece 10 and is transmitted from moving means 80 to plasma source 15 by transfer bar 81. Transfer bar 81 is configured in such a way that supply line 70 is passed through transfer bar 81.

Thus, it is seen that the objects of the present invention are efficiently obtained, although modifications and changes to the invention should be readily apparent to those having ordinary skill in the art, which modifications are intended to be within the spirit and scope of the invention as claimed. It also is understood that the foregoing description is illustrative of the present invention and should not be considered as limiting. Therefore, other embodiments of the present invention are possible without departing from the spirit and scope of the present invention.

### List of Reference Numerals

1 Apparatus for plasma treatment
5 surface of a workpiece,
6 workpiece holder
7 circumference of a workpiece
8 inner surface of a workpiece
10 workpiece
11 outer contour of a workpiece
13 top side of a planar extended workpiece
14 bottom side of a planar extended workpiece
15 plasma source
152 plasma source
16 electrode
162 electrode
17 gas supply
18 discharge space
20 power supply
202 power supply
21 ground potential
22 power supply
25 plasma
252 plasma
26 opening
262 opening
27 average distance traveled by the plasma
30 closed space
31 process chamber
32 opposite walls
35 extraction
40 plasma distribution element
402 further plasma distribution element
41 fractal plasma distribution element
42 pipe section
45 plasma discharge opening of a plasma distribution element
452 plasma discharge opening of a plasma distribution element
50 plasma jet
502 plasma jet
55 direction of a plasma jet
60 supply flange
61 bushing
65 extraction flange
66 sealing element
70 supply line
75 inner surface of a workpiece formed as a hollow body
80 moving means
81 transfer bar
85 relative movement
Δp pressure difference between plasma source and closed space
Δp₂ pressure difference between plasma source and closed space
S flow direction of a plasma
S₂ flow direction of a plasma
N normal vector of a plane of a plasma discharge opening
E plane of a plasma discharge opening
A cross section of a plasma discharge opening
α opening angle of a plasma jet
d₁ distance of the plasma discharge openings from the surface of the workpiece
d₂ distance of the plasma discharge openings from the surface of the workpiece
Q cross section of a pipe section
M lateral surface of a plasma distribution element
L longitudinal axis of a workpiece

What is claimed is:

1. An apparatus for the plasma treatment of surfaces of at least one workpiece, comprising:
a closed space;
at least one plasma source connected with a power supply for the generation of a plasma;
a single opening of the closed space provides fluid communication with a respective plasma distribution element which is located within the closed space;
at least one extraction for setting a pressure difference between the at least one plasma source and the closed space; and
a plurality of plasma discharge openings each plasma distribution element exhibits.

2. The apparatus recited in claim 1, wherein the opening of the at least one plasma source is a controllable nozzle or a controllable valve.

3. The apparatus recited in claim 1, wherein the at least one plasma distribution element is configured in such a way that a normal vector of a plane of each plasma discharge opening is directed onto a surface to be treated of the at least one workpiece, and wherein the normal vector of the plane of the respective plasma discharge opening defines a direction of a plasma jet.

4. The apparatus recited in claim 1, wherein the at least one plasma distribution element is a fractal plasma distribution element.

5. The apparatus recited in claim 1, wherein the at least one plasma distribution element is configured in such a way that plasma discharge openings are arranged opposite a top side and a bottom side of a planar extended workpiece.

6. The apparatus recited in claim 5, wherein the closed space has opposite walls provided with a respective at least one plasma source, to which there corresponds a respective plasma distribution element, so that the plasma discharge openings of the respective plasma distribution element are opposite the top side and the bottom side, respectively, of the planar extended workpiece.

7. The apparatus recited in claim 5, wherein the at least one plasma distribution element is a fractal plasma distribution element.

8. The apparatus recited in claim 1, wherein the plasma discharge openings of the at least one plasma distribution element are distributed homogeneously around a circumference of the surface to be treated of the workpiece.

9. The apparatus recited in claim 1, wherein the at least one plasma distribution element is configured as a hollow body, and the plasma discharge openings are distributed homogeneously over a lateral surface (M) of the at least one plasma distribution element.

10. The apparatus recited in claim 9, wherein the closed space is defined by the workpiece itself, shaped as a hollow body, a supply flange and an extraction flange, wherein through the supply flange there extends into the closed space at least one supply line, at the free end of which there are located the at least one plasma source and the at least one plasma distribution element, and wherein the closed space is in fluid communication with the extraction via an extraction flange.

11. The apparatus recited in claim 9, wherein the plasma discharge openings of the plasma distribution element are distributed homogeneously in relation to an inner surface of the workpiece shaped as a hollow body.

12. The apparatus recited in claim 1, wherein the power supply is a pulsed DC source, so that a pulsating plasma can be generated.

13. The apparatus recited in claim 1, wherein a moving means is provided which generates a relative movement between the plasma discharge openings and the at least one workpiece.

14. The method for the plasma treatment of surfaces of at least one workpiece, comprising the following steps:
maintaining a pressure difference between at least one plasma source and a closed space by means of an extractions;
generating a plasma in the at least one plasma source;
supplying the plasma via a respective single opening of the at least one plasma source into a respective plasma distribution element located in the closed space; and,
supplying in a directed fashion a plurality of plasma jets via a plurality of plasma discharge openings of each plasma distribution element to at least one surface of the at least one workpiece.

15. The method recited in claim 14, wherein the pressure difference between the at least one plasma source and the closed space is additionally controlled via the respective opening, configured as a controllable nozzle or a controllable valve, of the at least one plasma source.

16. The method recited in claim 14 wherein the plasma generated is a pulsating plasma.

17. The method recited in claim 14, wherein between the plasma discharge openings of the at least one plasma distribution element and the at least one workpiece a relative movement is performed.

18. An apparatus for the plasma treatment of surfaces of at least one workpiece, comprising:
a closed space;
at least one plasma source connected with a power supply for the generation of a plasma;
a single controllable nozzle or a single controllable valve is assigned to each plasma source and is in fluid communication with a respective fractal plasma distribution element, located within the closed space;
at least one extraction for setting a pressure difference between the at least one plasma source and the closed space; and
a plurality of plasma discharge openings each plasma distribution element exhibits.

19. An apparatus for the plasma treatment of surfaces of at least one workpiece, comprising:
a closed space;
at least one plasma source connected with a power supply for the generation of a plasma;
a single controllable nozzle or a single controllable valve is assigned to each plasma source and is in fluid communication with a respective plasma distribution element, located within the closed space, the at least one plasma distribution element is configured in such a way that plasma discharge openings are arranged opposite a top side and a bottom side of a workpiece;
at least one extraction for setting a pressure difference between the at least one plasma source and the closed space; and
a plurality of plasma discharge openings each plasma distribution element exhibits.

20. An apparatus for the plasma treatment of surfaces of at least one workpiece, comprising:
a closed space;
at least one plasma source connected with a power supply for the generation of a plasma;
a single controllable nozzle or a single controllable valve is assigned to each plasma source and is in fluid communication with a respective plasma distribution element, located within the closed space, the at least one plasma distribution element is configured in such a way that plasma discharge openings are distributed homogeneously around a circumference of the surface to be treated of the workpiece;
at least one extraction for setting a pressure difference between the at least one plasma source and the closed space; and
a plurality of plasma discharge openings each plasma distribution element exhibits.

21. An apparatus for the plasma treatment of surfaces of at least one workpiece, comprising:
a closed space;
at least one plasma source connected with a power supply for the generation of a plasma;
a single controllable nozzle or a single controllable valve is assigned to each plasma source and is in fluid communication with a respective plasma distribution element is configured as a hollow body, and a plurality of plasma discharge openings is distributed homogeneously over a lateral surface of the at least one plasma distribution element;
at least one extraction for setting a pressure difference between the at least one plasma source and the closed space; and
a plurality of plasma discharge openings each plasma distribution element exhibits.
